(19) United States
(12) Patent Application Publication
(10) Pub. No.: US 2012/0168905 A1
(43) Pub. Date: Jul. 5, 2012

(54) CAPACITOR OF NONVOLATILE MEMORY DEVICE

(76) Inventor: Je Il RYU, Seoul (KR)

(21) Appl. No.: 13/288,399

(22) Filed: Nov. 3, 2011

(30) Foreign Application Priority Data
Dec. 30, 2010 (KR) 10-2010-0139179

(51) Int. Cl. H01L 29/92; H01L 21/02

(52) U.S. Cl. 257/534; 438/381; 257/E21.008; 257/E29.342

(57) ABSTRACT

The capacitor of a nonvolatile memory device includes first and second electrodes formed in the capacitor region of a semiconductor substrate to respectively have consecutive concave and convex shape of side surfaces formed along each other and a dielectric layer formed between the first and the second electrodes.

### CROSS-REFERENCE TO RELATED APPLICATION

Priority to Korean patent application number 10-2010-0139179 filed on Dec. 30, 2010, the entire disclosure of which is incorporated by reference herein, is claimed.

### BACKGROUND

An exemplary embodiment relates to the capacitor of a nonvolatile memory device and, more particularly, to the capacitor of a nonvolatile memory device for increasing capacitance.

A nonvolatile memory device includes a pump circuit for generating voltages for a program operation, a read operation, and an erase operation. The pump circuit may include a plurality of capacitors for pumping operations.

FIG. 1 is a cross-sectional view showing the capacitor of a conventional nonvolatile memory device.

Referring to FIG. 1, a tunnel insulating layer 11, a conductive layer 12 for a floating gate, a dielectric layer 13, a conductive layer 14 for a control gate, and a metal layer 15 are sequentially stacked over a semiconductor substrate 10. The conductive layer 14 penetrates the dielectric layer 13, being electrically coupled to the conductive layer 12. A first node is coupled to the junction 16 of the semiconductor substrate 10, and a second node is coupled to the metal layer 15.

The capacitors of the conventional nonvolatile memory device may be formed when memory cells are fabricated. The conductive layer 14 for a control gate and the conductive layer 12 for a floating gate are electrically coupled to form a capacitor structure.

In order to increase capacitance of the capacitor, the area of the conductive layer 12 may be increased. In this case, however, the degree of integration of nonvolatile memory devices may be adversely affected.

### BRIEF SUMMARY

An exemplary embodiment relates to the capacitor of a nonvolatile memory device having increased capacitance.

A capacitor of a nonvolatile memory device according to an aspect of the present disclosure includes first and second electrodes formed in a capacitor region of a semiconductor substrate to respectively have consecutive concave and convex shape of side surfaces formed along each other, and a dielectric layer formed between the first and second electrodes.

A capacitor of a nonvolatile memory device according to another aspect of the present disclosure includes first and second lower electrodes formed in a capacitor region of a semiconductor substrate to each have a rake structure, wherein fingers of each rake structure alternate with the fingers of the other rake structure, a first dielectric layer formed between the first and second lower electrodes and over the first and second lower electrodes, first and second upper electrodes formed on the first dielectric layer to each have a rake structure, wherein fingers of each rake structure alternate with the fingers of the other rake structure, and a second dielectric layer formed between the first and the second upper electrodes.

### BRIEF DESCRIPTION OF THE DRAWINGS

FIG. 1 is a cross-sectional view showing the capacitor of a conventional nonvolatile memory device; and

FIGS. 2A to 2H are cross-sectional views and plan views illustrating a method of forming the capacitor of a nonvolatile memory device according to an exemplary embodiment of this disclosure.

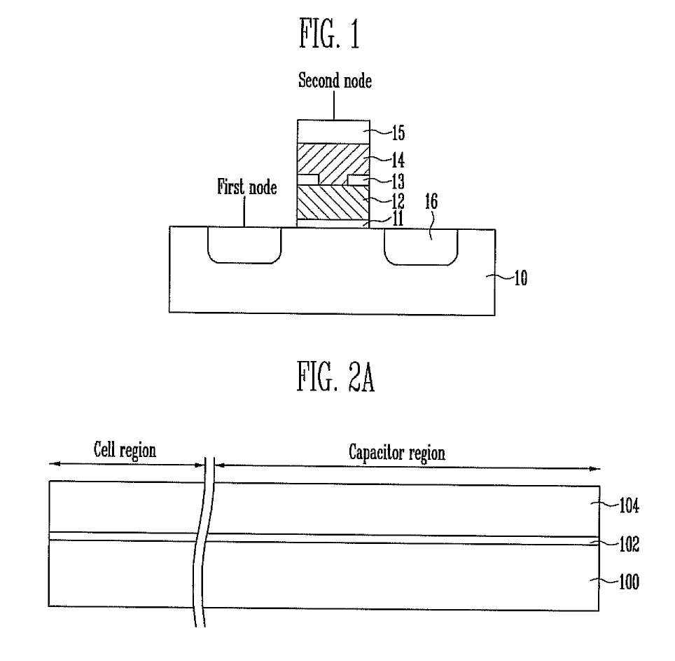

### DESCRIPTION OF EMBODIMENT

Hereinafter, an exemplary embodiment of the present disclosure will be described in detail with reference to the accompanying drawings. The figures are provided to enable those of ordinary skill in the art to make and use the embodiment of the disclosure.

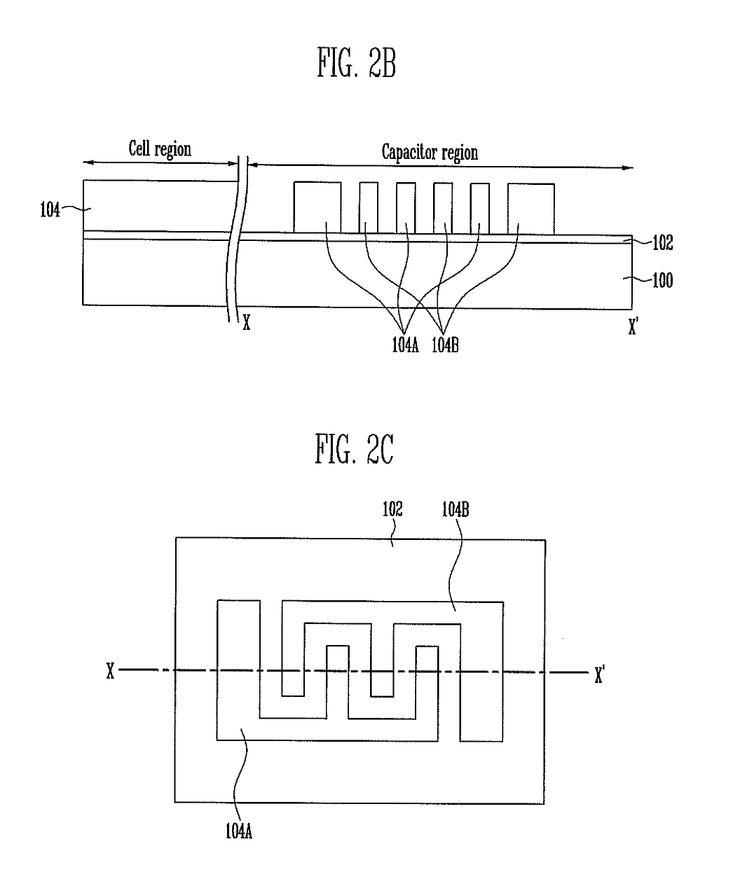

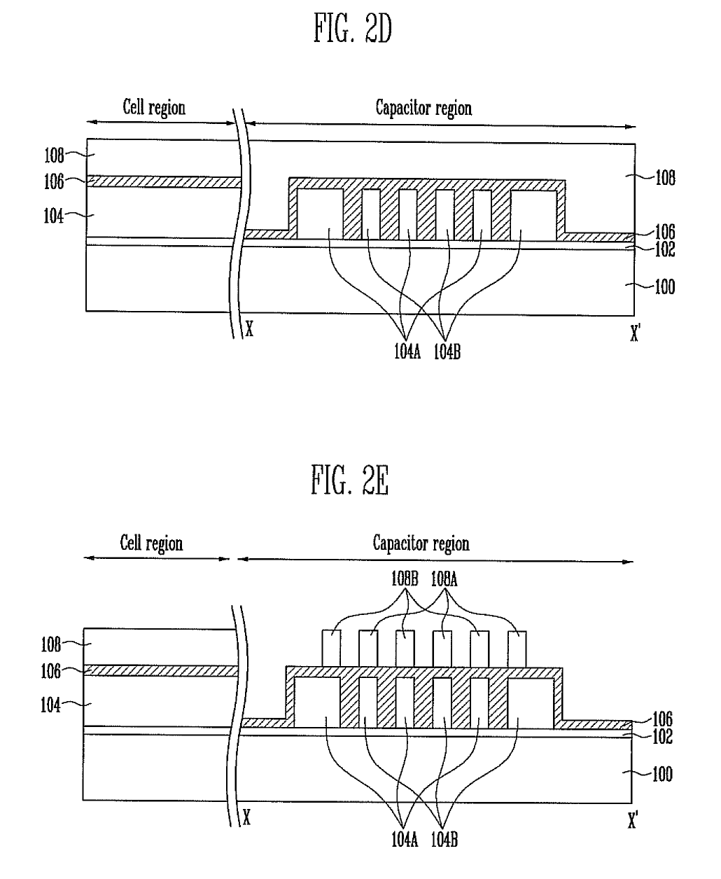

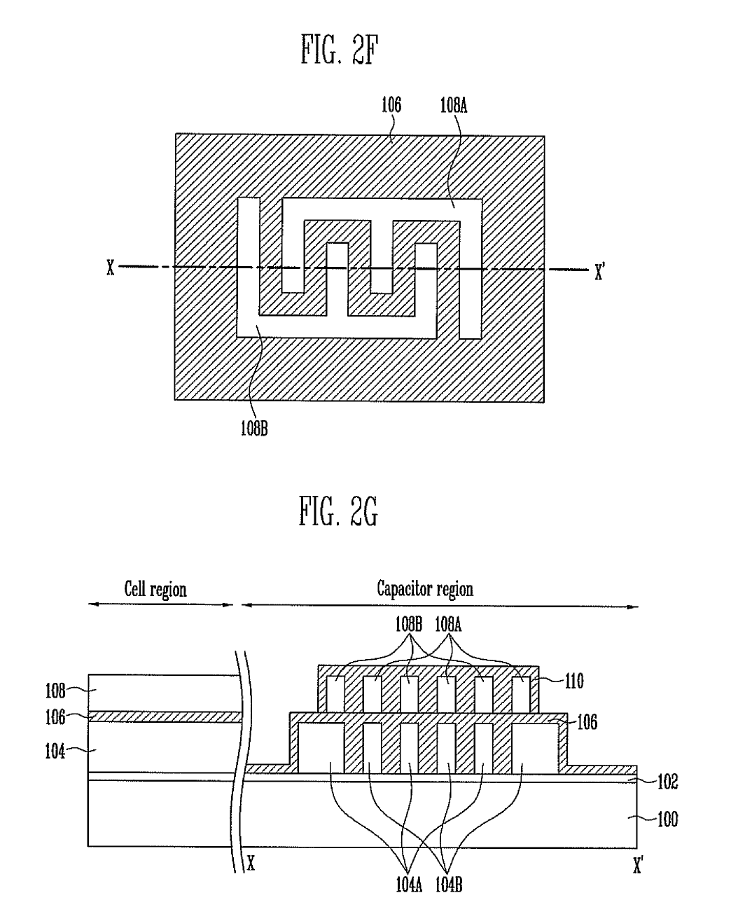

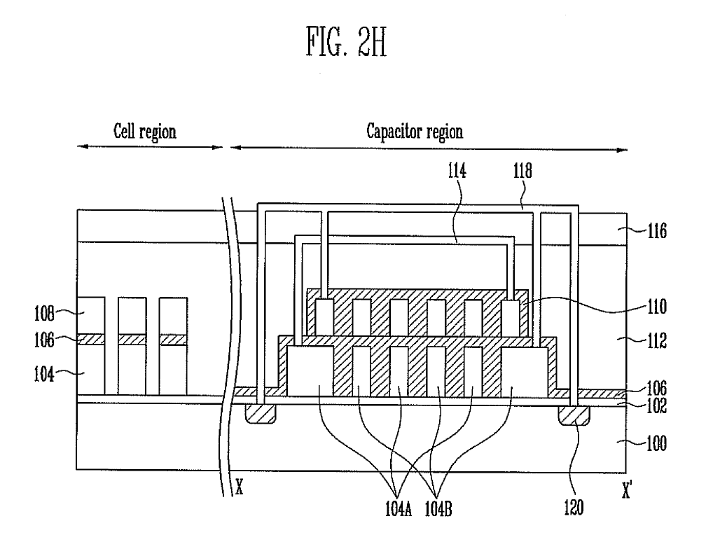

FIGS. 2A to 2H are cross-sectional views and plan views illustrating a method of forming the capacitor of a nonvolatile memory device according to an exemplary embodiment of this disclosure.

Referring to FIG. 2A, a tunnel insulating layer 102 and a conductive layer 104 for a floating gate are sequentially stacked over a semiconductor substrate 100, including a cell region in which memory cells will be formed and a capacitor region in which a capacitor will be formed.

The tunnel insulating layer 102 may be preferably formed of an oxide layer. The conductive layer 104 may be preferably formed of a polysilicon layer.

Referring to FIG. 2B, first lower electrode patterns 104A and second lower electrode patterns 104b are formed by patterning the conductive layer 104 formed in the capacitor region. The first lower electrode patterns 104A may be defined as odd-numbered patterns of the plurality of patterns, and the second lower electrode patterns 104B may be defined as even-numbered patterns of the plurality of patterns. Furthermore, the first lower electrode patterns 104A and the second lower electrode patterns 104B are alternately arranged. It is preferred that the outermost patterns of the first lower electrode patterns 104A and the second lower electrode patterns 104B be formed to have greater critical dimensions than other patterns. This is for securing a margin in forming contact holes for subsequent electrode lines.

FIG. 2C is a plan view illustrating the semiconductor device shown in FIG. 2B. For reference, FIG. 2B show a cross-sectional views taken along a line XX′ of FIG. 2C. Referring to FIG. 2C, the first lower electrode patterns 104A includes the plurality of parallel patterns (that is, odd-numbered patterns) having their ends coupled, and the second lower electrode patterns 104B includes the plurality of parallel patterns (that is, even-numbered patterns) having their ends coupled. That is, the first lower electrode patterns 104A and the second lower electrode patterns 104B have a consecutive concave and convex ( [symbol] [symbol] ) shape. The first lower electrode patterns 104A and the second lower electrode patterns 104B are formed complementarily. More particularly, the concave ( [symbol] ) portions and convex ( [symbol] ) portions of the first lower electrode patterns 104A are formed to face the convex ( [symbol] ) portions and concave ( [symbol] ) portions of the second lower electrode patterns 104B, respectively. Furthermore, the convex portions of the second lower electrode patterns 104B are formed in the respective concave portions of the first lower electrode patterns 104A, and the convex portions of the first lower electrode patterns 104A are formed in the respective concave portions of the second lower electrode patterns 104B. That is, the first and the second lower electrode patterns 104A and 104B have a crossing finger structure (that is, each electrode forms a rake structure, where fingers of each rake structure alternate with the fingers of the other rake structure).

Referring to FIG. 2D, a first dielectric layer 106 and a conductive layer 108 for a control gate are formed on entire structure, including the conductive layer 104 of the cell region and the first and the second lower electrode patterns 104A and 104B of the capacitor region. The first dielectric layer 106 may preferably have an ONO structure in which a first oxide layer, a nitride layer, and a second oxide layer are sequentially stacked. It is preferred that the conductive layer 108 for a control gate be formed of a polysilicon layer.

Referring to FIG. 2E, first upper electrode patterns 108A and second upper electrode patterns 108b are formed by patterning the conductive layer 108 formed in the capacitor region. The first upper electrode patterns 108A may be defined as even-numbered patterns of the plurality of patterns, and the second upper electrode patterns 108B may be defined as odd-numbered patterns of the plurality of patterns. That is, the second upper electrode patterns 108B are formed over the first lower electrode patterns 104A, and the first upper electrode patterns 108A are formed over the second lower electrode patterns 104B. Furthermore, the first upper electrode patterns 108A and the second upper electrode patterns 108B are alternately arranged.

FIG. 2F is a plan view illustrating the semiconductor device shown in FIG. 2E. For reference, FIG. 2E shows a cross-sectional views taken along a lines XX′ of FIG. 2F. Referring to FIG. 2F, the first upper electrode patterns 108A includes the plurality of parallel patterns (that is, even-numbered patterns) having their ends coupled, and the second upper electrode patterns 108B includes the plurality of parallel patterns (that is, odd-numbered patterns) having their ends coupled. That is, the first upper electrode patterns 108A and the second upper electrode patterns 108B have a consecutive concave and convex ( [symbol] [symbol] ) shape. The first upper electrode patterns 108A and the second upper electrode patterns 108B are formed complementarily. More particularly, the concave ( [symbol] ) portions and convex ( [symbol] ) portions of the first upper electrode patterns 108A are formed to face the convex ( [symbol] ) portions and concave ( [symbol] ) portions of the second upper electrode patterns, respectively. Furthermore, the convex portions of the second upper electrode patterns 108B are formed in the respective concave portions of the first upper electrode patterns 108A, and the convex portions of the first upper electrode patterns 108A are formed in the respective concave portions of the second upper electrode patterns 108B. That is, the first and the second upper electrode patterns 108A and 108B have a crossing finger structure.

Referring to FIG. 2G, a second dielectric layer 110 is formed in the capacitor region, including the first upper electrode patterns 108A and the second upper electrode patterns 108B. The first lower electrode patterns 104A, the second lower electrode patterns 104B, the first upper electrode patterns 108A, and the second upper electrode patterns 108B are surrounded by the first and second dielectric layers 106 and 110. The second dielectric layer 110 may not be formed in the cell region.

Referring to FIG. 2H, gate patterns are formed by patterning the conductive layer 108 for a control gate, the first dielectric layer 106, and the conductive layer 104 for a floating gate which is formed in the cell region. Next, a first interlayer dielectric layer 112 is formed on the entire structure, including the gate patterns of the cell region and the second dielectric layer 110 of the capacitor region. Next, contact holes are formed by etching the first interlayer dielectric layer 112, the first dielectric layer 106, and the second dielectric layer 108 such that part of the top surface of an outermost pattern of the first lower electrode patterns 104A and part of the top surface of an outermost pattern of the first upper electrode patterns 108A are exposed. The contact holes are filled with a conductive material and are coupled to form a first electrode line 114.

Next, a second interlayer dielectric layer 116 is formed on the entire structure including the first electrode line 114. Next, contact holes are formed by etching the first interlayer dielectric layer 112, the first dielectric layer 106, the second dielectric layer 108, and the tunnel insulating layer 102 such that part of the top surface of an outermost pattern of the second lower electrode patterns 104B, part of the top surface of an outermost pattern of the second upper electrode patterns 108B, and parts of the semiconductor substrate 100 are exposed. The contact holes are filled with a conductive material and are coupled to form a second electrode line 118. Here, it is preferred that junctions 120 be formed in the semiconductor substrate, exposed through the contact holes, by performing an ion implantation process after forming the contact holes.

According to the capacitor formation method, the first lower electrode patterns 104A and the second lower electrode patterns 104B are formed using the conductive layer 104 for a floating gate and have the concave and convex ( [symbol] [symbol] ) structure in order to increase the contact areas. Accordingly, capacitance of the capacitor can be increased. Furthermore, the second upper electrode patterns 108B and the first upper electrode patterns 108A are formed over the first lower electrode patterns 104A and the second lower electrode patterns 104B, respectively, using the conductive layer 108 for a control gate. Accordingly, capacitance of the capacitor can be further increased. Furthermore, the electrode line is coupled to the semiconductor substrate, thereby generating capacitance between the semiconductor substrate and the first lower electrode patterns 104A. Accordingly, capacitance can be further increased.

According to the exemplary embodiment of this disclosure, the first and the second electrodes having a concave and convex ( [symbol] [symbol] ) shape opposite to each other are formed by using the conductive layer for a floating gate of a memory cell. Accordingly, the contact areas between the first and second electrodes can be optimized/maximized, and capacitance of a capacitor can be increased.

What is claimed is:

1. A capacitor of a nonvolatile memory device, comprising:
first and second electrodes formed in a capacitor region of a semiconductor substrate to respectively have consecutive concave and convex shaped side surfaces that are formed side by side; and
a dielectric layer formed between the first and second electrodes.

2. The capacitor of claim 1, wherein a concave portion and a convex portion of the first electrode are formed to face a convex portion and a concave portion of the second electrode, respectively.

3. The capacitor of claim 1, wherein:
a convex portion of the second electrode is formed in a concave portion of the first electrode, and
a convex portion of the first electrode is formed in a concave portion of the second electrode.

4. The capacitor of claim 1, further comprising:
an interlayer dielectric layer formed over the first and the second electrodes; and
third and fourth electrodes formed over the interlayer dielectric layer to respectively have concave and convex shaped side surfaces that are formed side by side.

5. The capacitor of claim 4, wherein:
the third electrode is formed over the second electrode, and
the fourth electrode is formed over the first electrode.

6. The capacitor of claim 4, further comprising:
a first electrode line coupling the third electrode to the first electrode; and
a second electrode line coupling the fourth electrode to the second electrode.

7. The capacitor of claim 1, further comprising an insulating layer formed at an interface between the first electrode and the semiconductor substrate and between the second electrode and the semiconductor substrate.

8. The capacitor of claim 7, further comprising electrode lines coupling the semiconductor substrate to the second electrode.

9. The capacitor of claim 1, wherein the first and the second electrodes are formed of a conductive layer for a floating gate.

10. The capacitor of claim 4, wherein the third and the fourth electrodes are formed of a conductive layer for a control gate.

11. A capacitor of a nonvolatile memory device, comprising:
first and second lower electrodes formed in a capacitor region of a semiconductor substrate to each have a rake structure, wherein fingers of each rake structure alternate with the fingers of the other rake structure;
a first dielectric layer formed between the first and second lower electrodes and over the first and second lower electrodes;
first and second upper electrodes formed on the first dielectric layer to each have a rake structure, wherein fingers of each rake structure alternate with the fingers of the other rake structure have a crossing finger structure; and
a second dielectric layer formed between the first and the second upper electrodes.

12. The capacitor of claim 11, wherein a concave portion and a convex portion of the side of the first lower electrode are formed to face a convex portion and concave portion of the side of the second lower electrode, respectively.

13. The capacitor of claim 11, wherein:
a convex portion of the side of the second lower electrode is formed in a concave portion of the side of the first lower electrode, and
a convex portion of the side of the first lower electrode is formed in a concave portion of the side of the second lower electrode.

14. The capacitor of claim 11, wherein:
the first upper electrode is formed over the second lower electrode, and
the second upper electrode is formed over the first lower electrode.

15. The capacitor of claim 11, further comprising:
a first electrode line coupling the first upper electrode to the first lower electrode; and
a second electrode line coupling the second upper electrode to the second lower electrode.

16. The capacitor of claim 11, further comprising an insulating layer formed at an interface between the first and second lower electrodes and the semiconductor substrate.

17. The capacitor of claim 16, further comprising electrode lines coupling the semiconductor substrate to the second lower electrode.

18. The capacitor of claim 11, wherein the first and the second lower electrodes are formed of a conductive layer for a floating gate.

19. The capacitor of claim 11, wherein the first and the second upper electrodes are formed of a conductive layer for a control gate.
